(19) United States
(12) Patent Application Publication
(10) Pub. No.: US 2012/0181450 A1
(43) Pub. Date: Jul. 19, 2012

(54) METHOD AND APPARATUS FOR DETECTING BIO MATERIAL USING PHOTOELECTRIC CONVERSION DEVICE, AND METHOD FOR MANUFACTURING PHOTOELECTRIC CONVERSION DEVICE

(75) Inventors: Kwan Su KIM, Daejeon (KR); Hee Kyung SUNG, Daejeon (KR); Jongil JU, Daejeon (KR); Jung Min CHO, Daejeon (KR); Kibong SONG, Daejeon (KR)

(73) Assignee: ELECTRONICS AND TELECOMMUNICATIONS RESEARCH INSTITUTE, Daejeon (KR)

(21) Appl. No.: 13/351,898

(22) Filed: Jan. 17, 2012

(30) Foreign Application Priority Data
Jan. 18, 2011 (KR) 10-2011-0005036
Sep. 15, 2011 (KR) 10-2011-0093040

(51) Int. Cl. G01N 21/64; H01L 31/18

(52) U.S. Cl. 250/459.1; 250/458.1; 438/70; 250/200; 257/E31.127

(57) ABSTRACT

An apparatus for detecting a bio material includes: an conjugate of a bio material and a fluorescent material to be excited and emit light of a lower energy than an energy of incident light by virtue of the fluorescent material when the light is incident; and an optical filter for allowing the excitation-emitted light from the conjugate, among the incident light, to be transmitted therethrough. The apparatus further includes a photoelectric conversion device for converting the light transmitted through the optical filter into an electric signal.

### CROSS-REFERENCE(S) TO RELATED APPLICATION(S)

The present invention claims priorities of Korean Patent Applications No. 10-2011-0005036, filed on Jan. 18, 2011 and No. 10-2011-0093040, filed on Sep. 15, 2011, which are incorporated herein by references.

### FIELD OF THE INVENTION

The present invention relates to a technique of detecting a bio material using a photoelectric conversion device, and more particularly, to a method and apparatus for detecting a bio material, such as beta-amyloid protein or the like, as a primary cause of Alzheimer's disease, and a method for fabricating a photoelectric conversion device.

### BACKGROUND OF THE INVENTION

As well-known in the art, dementia is a type of brain disorder, which seriously affects personal activities. A typical type of dementia occurred in the aged is Alzheimer's disease. The Alzheimer's disease is a degenerative neurological disorder, which occurs in a portion of a brain responsible for a thinking ability, a memory and a language. The cause of the Alzheimer's disease has not been uncovered yet, and there is no cure for the disease. With injecting drugs such as tacrine (Cognex), donepezil (Aricept), rivastigmine (Exelon) or galantamine (razadyne well known as reminyl), the progressing of symptoms of the disease may be temporarily delayed for people who suffer from the Alzheimer's disease in the early and intermediate stages. This disease is characterized by the loss of cognitive functions, and neuropathologically exhibits the presence of neurofibrillary tangles within cells in the brain and the presence of intracellular deposit of beta-amyloid peptide, which forms amyloid plaques.

For diagnosis of the diseases such as Alzheimer's disease and the like, a bio sensor can be used. Most of bio sensors have a principle of measuring a causal material of a disease directly or indirectly. Various researches are being done on methods for measuring causal materials of diseases using such bio sensors. Especially, many researches are undergoing for curing Alzheimer's disease through various approaches, but relatively fewer efforts are being made for studying on an early diagnosis of Alzheimer's disease in a simple manner.

In the prior art, the early diagnosis of Alzheimer's disease is realized by combining beta-amyloid as the primary cause of the Alzheimer's disease with a fluorescent material to check an expression status by viewing through a microscope, or by a gene analysis.

However, since the early diagnosis method according to the prior art uses a chemical method, it results in difficulty in a real-time diagnosis, a high-priced diagnosis, and difficulty in a mass production of Alzheimer's disease diagnosis kit.

### SUMMARY OF THE INVENTION

In view of the above, the present invention provides an apparatus for detecting a bio material, which is capable of detecting a bio material, such as beta-amyloid protein or the like as a primary causal material of Alzheimer's disease, by use of an optical filter and a photoelectric conversion device.

Further, the present invention provides a method for detecting a bio material by a bio material detection apparatus including an optical filter through which light with a specific wavelength band is transmitted.

Furthermore, the present invention provides a method for fabricating a photoelectric conversion device, which can be used for detection of a bio material.

In accordance with an aspect of the present invention, there is provided an apparatus for detecting a bio material. The apparatus includes: a conjugate of a bio material and a fluorescent material which is excited and emits light of a lower energy than an energy of incident light by virtue of the fluorescent material when the light is incident; an optical filter for allowing the excitation-emitted light from the conjugate, among the incident light, to be transmitted therethrough; and a photoelectric conversion device for converting the light transmitted through the optical filter into an electric signal.

In accordance with another aspect of the present invention, there is provided a method for detecting a bio material by a bio material detection apparatus. The method includes: exciting and emitting light of a lower energy than an energy of incident light by virtue of a fluorescent material when the light is incident into a conjugate of the bio material and the fluorescent material; allowing the excitation-emitted light from the conjugate to be transmitted through an optical filter; and converting the light transmitted through the optical filter into an electric signal.

In accordance with still another aspect of the present invention, there is provided a method for fabricating a photoelectric conversion device for converting excitation-emitted light from a conjugate of a bio material and a fluorescent material into an electric signal. The method includes: forming a photo transistor; and forming an optical filter for allowing the excitation-emitted light from the conjugate, among incident light, to be transmitted therethrough, on the photo transistor.

### BRIEF DESCRIPTION OF THE DRAWINGS

The objects and features of the present invention will become apparent from the following description of embodiments, given in conjunction with the accompanying drawings, in which:

FIG. 1 is a diagram showing the configuration of a bio material detection apparatus using a photoelectric conversion device in accordance with an embodiment of the present invention;

FIG. 2 is a graph showing an optical characteristic condition which an optical filter used in the bio material detection apparatus in accordance with an embodiment of the present invention should have;

FIGS. 3A to 3E show a method for fabricating a photoelectric conversion device in accordance with an embodiment of the present invention;

FIG. 4A presents the photoelectric conversion device 130 fabricated in accordance with the embodiment of the present invention and FIG. 4B is an image thereof which can be observed by using an optical microscope;

FIG. 5 is a graph showing an optical transmission characteristic curve of arsenic trisulfide used as an optical material of an optical filter in accordance with an embodiment of the present invention;

FIG. 6 is a graph showing a photocurrent characteristic of a photo transistor used as the photoelectric conversion device in accordance with an embodiment of the present invention;

FIG. 7 is a graph showing a photocurrent characteristic of the photo transistor including an optical filter that uses arsenic trisulfide as an optical material in accordance with an embodiment of the present invention;

FIG. 8 is a graph showing a photocurrent characteristic when the photo transistor converts a fluorescent signal into an electric signal in accordance with an embodiment of the present invention; and

FIG. 9A is a cross sectional view showing a photoelectric conversion device on which a microfluidic channel is formed in a bio material detection apparatus in accordance with another embodiment of the present invention, and FIG. 9B shows an image of a photoelectric conversion device further including the microfluidic channel which can be observed by using an optical microscope.

### DETAILED DESCRIPTION OF THE EMBODIMENTS

Embodiments of the present invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

In the following description of the present invention, if the detailed description of the already known structure and operation may confuse the subject matter of the present invention, the detailed description thereof will be omitted. The following terms are terminologies defined by considering functions in the embodiments of the present invention and may be changed operators intend for the invention and practice. Hence, the terms should be defined throughout the description of the present invention.

Combinations of respective blocks of block diagrams attached herein and respective steps of a sequence diagram attached herein may be carried out by computer program instructions. Since the computer program instructions may be loaded in processors of a general purpose computer, a special purpose computer, or other programmable data processing apparatus, the instructions, carried out by the processor of the computer or other programmable data processing apparatus, create devices for performing functions described in the respective blocks of the block diagrams or in the respective steps of the sequence diagram. Since the computer program instructions, in order to implement functions in specific manner, may be stored in a memory useable or readable by a computer aiming for a computer or other programmable data processing apparatus, the instruction stored in the memory useable or readable by a computer may produce manufacturing items including an instruction device for performing functions described in the respective blocks of the block diagrams and in the respective steps of the sequence diagram. Since the computer program instructions may be loaded in a computer or other programmable data processing apparatus, instructions, a series of processing steps of which is executed in a computer or other programmable data processing apparatus to create processes executed by a computer so as to operate a computer or other programmable data processing apparatus, may provide steps for executing functions described in the respective blocks of the block diagrams and the respective steps of the sequence diagram.

Moreover, the respective blocks or the respective steps may indicate modules, segments, or some of codes including at least one executable instruction for executing a specific logical function(s). In several alternative embodiments, it is noticed that functions described in the blocks or the steps may run out of order. For example, two successive blocks and steps may be substantially executed simultaneously or often in reverse order according to corresponding functions.

Hereinafter, embodiments of the present invention will be described in detail with reference to the accompanying drawings which form a part hereof.

The embodiments of the present invention are directed to a technology applicable to a bio sensor technique requiring a selective sensing using a selective light transmission function of a specific material or specific structure. For example, this technology may detect an extremely small amount of beta-amyloid protein as a primary causal material of Alzheimer's disease. This technology may use an optical characteristic material which allows for transmission of light with a specific wavelength and a photo transistor (i.e., a photo-sensitive field effect transistor) capable of sensing transmitted light even with extremely low intensity. A fluorescent material combined with a material which causes a disease (i.e., causal material of disease) is excited and emitted as light of low energy by incident light of high energy, and such emitted light of the low energy is selectively transmitted through an optical filter. The photo transistor converts the transmitted light into an electric signal so as to detect the causal material of the disease. The present invention can be utilized for an early diagnosis of, e.g., Alzheimer's disease.

FIG. 1 shows a configuration of a bio material detection apparatus using a photoelectric conversion device in accordance with an embodiment of the present invention.

As shown in FIG. 1, a bio material detection apparatus 100 in accordance with the embodiment of the present invention includes a light source 110, a conjugate 120, a photoelectric conversion device 130, an optical filter 135 and a quantification processor 140.

First, the conjugate 120 is formed such that a bio material 121 contains a fluorescent material 122 by combining them. For example, the conjugate 120 may be formed by combining beta-amyloid protein or the like, which is a primary causal material of Alzheimer's disease, with the fluorescent material 122.

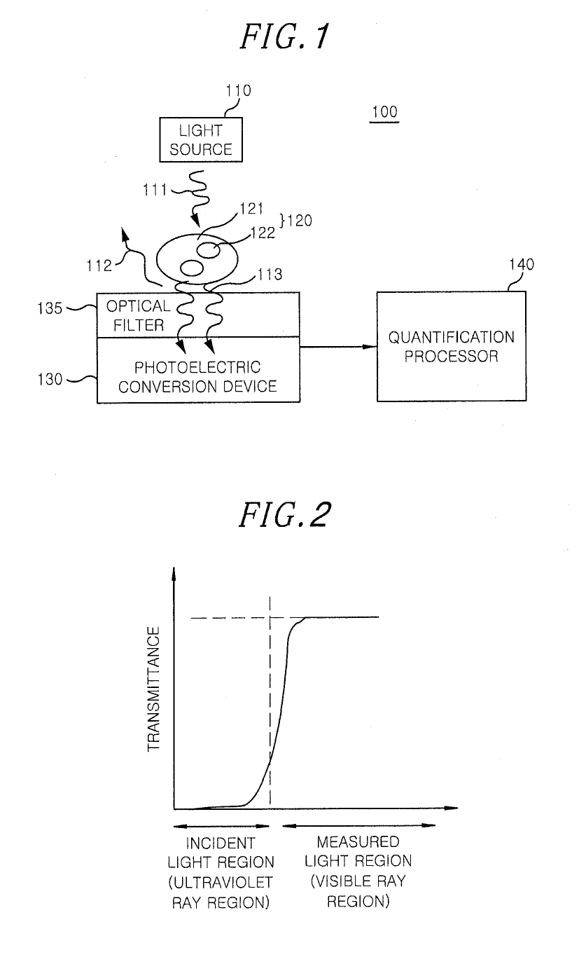

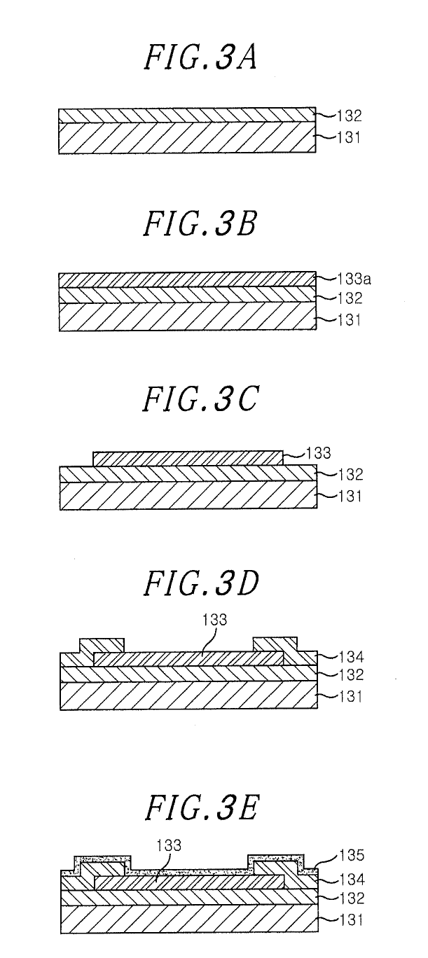

The photoelectric conversion device 130 uses a photo transistor having a gate, a channel region, a wire and the like formed thereon. The optical filter 135 may be implemented as a thin film, which is integrally formed with the photo transistor on an upper portion thereof by using an optical material, which reflects ultraviolet rays and transmits visible rays as shown in the graph in FIG. 2. The formation and fabrication process of the photoelectric conversion device 130 and the optical filter 135 will be described later with reference to FIGS. 3A to 3E.

In this bio material detection apparatus 100, when incident light 111 is incident from the light source 110 in a state that the bio material 121 and the fluorescent material 122 are combined with each other, the conjugate 120 excites light of lower energy than energy of the incident light 111 by the fluorescent material 122, thereby emitting fluorescence 113.

For example, when ultraviolet rays of wavelengths in a range from 380 nm to 400 nm are incident, the conjugate 120 emits blue visible fluorescence of a wavelength near 480 nm when the fluorescent material 122 is tioflavin T (ThT), while emitting green visible fluorescence of a wavelength near 520 nm when the fluorescent material 122 is fluorescein isothiocyanate (FITC)(yellowish green fluorescence).

The optical filter 135 reflects ultraviolet ray 112 among incident light, and transmits the visible fluorescence 113, which has been excited and emitted from the conjugate 120.

Then, the photoelectric conversion device 130 converts the light transmitted through the optical filter 135 into an electric signal, and the quantification processor 140 measures the electric signal converted by the photoelectric conversion device 130, thereby measuring an amount of a bio material.

FIGS. 3A to 3E present a method for fabricating the photoelectric conversion device 130 in accordance with an embodiment of the present invention.

As shown in FIGS. 3A to 3E, the method for fabricating the photoelectric conversion device 130, which is to convert excitation-emitted light from a conjugate of a bio material and a fluorescent material into an electric signal, includes forming the photo transistor, and forming the optical filter 135 for transmitting excitation-emitted light from the conjugate 120 among incident light on the photo transistor.

First, in FIG. 3A, an insulating film 132 such as silicon oxide (SiO₂) film or the like is formed on a semiconductor substrate 131 having a gate formed thereon. For example, the gate may have a back-gate structure, and the insulating film 132 may be formed with the silicon oxide film having a thickness of about 100 nm.

Next, a channel region 133 is formed on the insulating film 132 in FIGS. 3B and 3C. For example, the channel region 133 may be formed by forming an amorphous silicon layer 133a on the insulating film 132 and then patterning the amorphous silicon layer 133a.

Thereafter, a metal layer is formed on open regions of the insulating film 132 and the channel region 133, followed by patterning, thereby forming a wire 134 in FIG. 3D.

Then, on open regions of the channel region 133 and the wire 134, an optical filter 135 is formed by using an optical material, which reflects ultraviolet rays and transmits visible rays, in FIG. 3E.

For example, the optical filter 135 may be formed by depositing an optical material on the channel region 133 and the wire 134. The optical material may be, e.g., arsenic trisulfide (As₂S₃).

Further, the optical filter 135 may be formed by doping a semiconductor material such as selenium or the like on the optical material such as arsenic trisulfide or the like.

The photoelectric conversion device 130 and the optical filter 135 of the present invention may be fabricated depending on the flow of processes, as described with reference to FIGS. 3A to 3E, or be fabricated by using a process of producing a dichroic glass, which is one of optical devices, or the like.

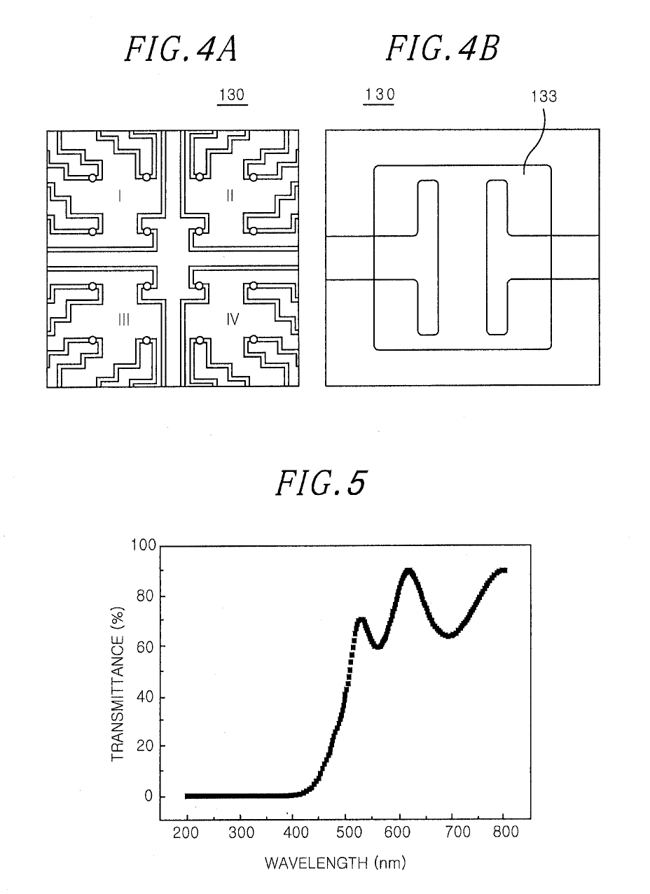

FIG. 4A presents the photoelectric conversion device 130 fabricated in accordance with the embodiment of the present invention and FIG. 4B is an image thereof which can be observed by using an optical microscope.

As shown in FIG. 4A, the photoelectric conversion device 130 may have a 4×4 array structure, and include, e.g., the channel region 133 of about 100 nm².

FIG. 5 is a graph showing an optical transmission characteristic curve of arsenic trisulfide used as the optical material of the optical filter 135 in accordance with the embodiment of the present invention.

It can be seen from FIG. 5 that the arsenic trisulfide as the optical material transmits visible rays within the range of from about 380 nm to 780 nm.

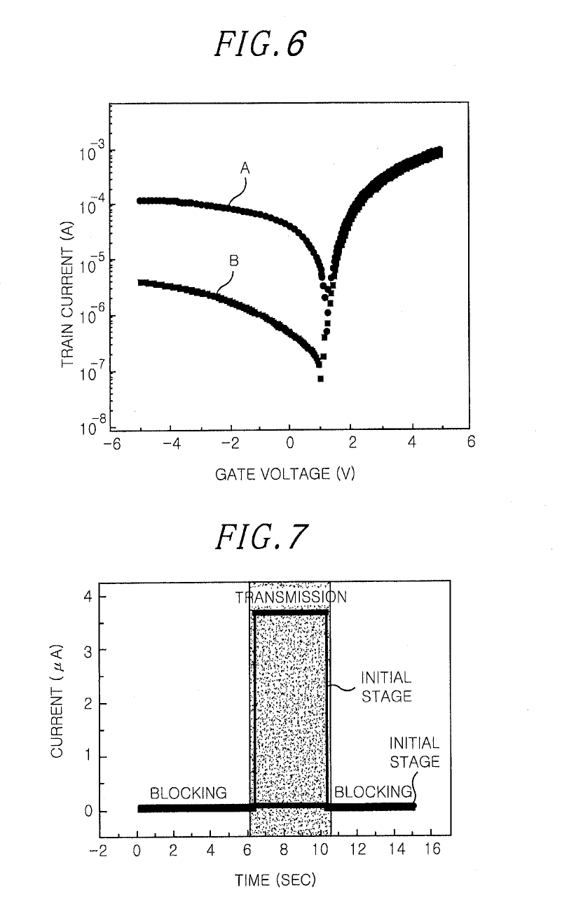

FIG. 6 is a graph showing a photocurrent characteristic of a photo transistor used as the photoelectric conversion device in accordance with the embodiment of the present invention.

Referring to FIG. 6, the photo transistor having an electric characteristic corresponding to a curve B exhibits an electric characteristic corresponding to a curve A when visible ray is incident. Hence, when the optical filter exhibiting the optical transmission characteristic as shown in FIG. 2 is deposited on the photo transistor, as mentioned above, it exhibits an electric characteristic curve similar to the curve B with respect to ultraviolet incident light. However, when visible fluorescent light, which is excited and emitted from the conjugate 120, is incident, then the photo transistor exhibits an electric characteristic similar to the curve A.

FIG. 7 is a graph showing a photocurrent characteristic of a photo transistor including an optical filter that uses arsenic trisulfide as an optical material in accordance with the embodiment of the present invention. FIG. 7 shows a photocurrent characteristic of a photo transistor by laser beams having a wavelength of about 400 nm.

As shown in FIG. 7, it can be noticed that a current is increased by an incident optical signal before forming the optical filter. However, it can be recognized that when the optical filter using an optical material is deposited right on the channel region, incident light may not be transmitted by the optical filter, so a photocurrent signal can be remarkably decreased. Therefore, the photo transistor having the optical filter can effectively detect only an optical signal emitted from the fluorescent material, with effectively removing an optical signal by laser beam which is incident for excitation of the fluorescent material.

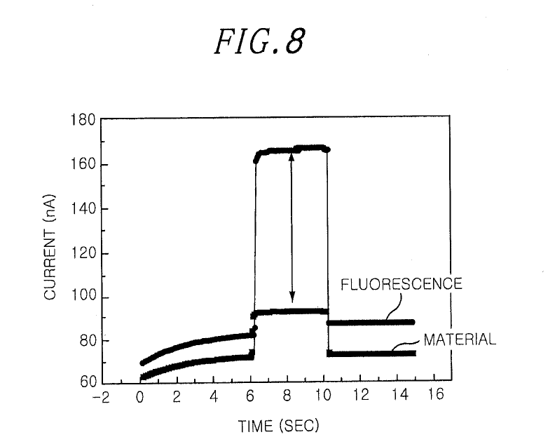

FIG. 8 is a graph showing a photocurrent characteristic when the photo transistor converts a fluorescent signal into an electric signal in accordance with the embodiment of the present invention.

It can be seen from FIG. 8 that when a ThT fluorescent material is not present over the channel region, the photo transistor exhibits an extremely low photocurrent characteristic of 100 nA due to the incident laser beam being blocked by the optical filter. However, it can be understood that when the ThT fluorescent material is present over the channel region, an optical signal of the photo transistor is increased by fluorescent light which is emitted when a fluorescent material is excited by incident laser beam. As illustrated in the embodiment of the present invention, it can be understood from the graph of FIG. 8 that a bio material can be quantified by use of the photoelectric conversion device, in which an optical filter is provided and the bio material is combined with a specific fluorescent material.

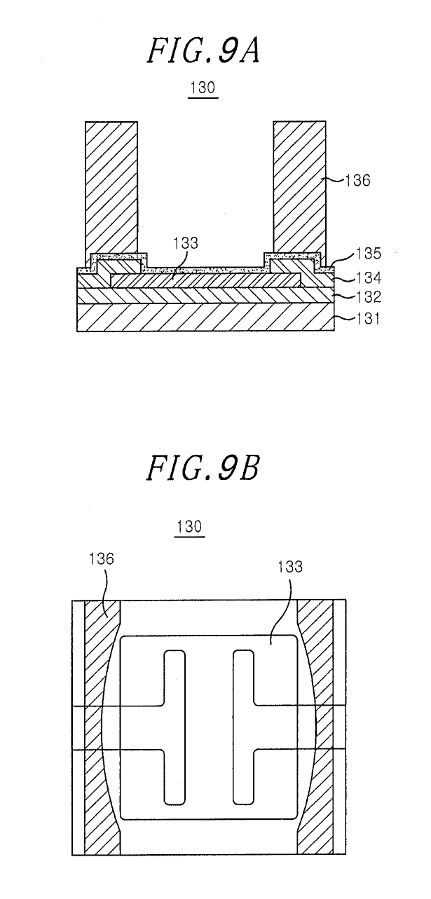

FIG. 9A is a cross sectional view showing a photoelectric conversion device on which a microfluidic channel 136 is formed in a bio material detection apparatus in accordance with another embodiment of the present invention, and FIG. 9B shows an image of a photoelectric conversion device further including the microfluidic channel 136 which can be observed by using an optical microscope.

As shown in FIGS. 9A and 9B, a microfluidic channel 136 may be additionally formed on the optical filter 135. The microfluidic channel 136 serves to guide the conjugate 120, which is formed by combining the bio material 121 with the fluorescent material 122, to be located exactly over the channel region, i.e., a central region of the optical filter 135. The microfluidic channel 136 may be formed of a material such as polydimethylsiloxane (PDMS) or the like.

Also, in order for the conjugate 120 to be proliferated with being easily attached onto the surface of the photoelectric conversion device 130, the surface of the photoelectric conversion device 130, namely, the optical filter 135 may experience an additional surface-processing. For example, the surface processing may be performed for the optical filter by using an extracellular matrix, such as fibronectin, galatin, collagen, laminin, or the like.

In accordance with the embodiments of the present invention, the use of selective light transmission of transmitting light having a specific wavelength band and photoelectric conversion can allow for detection of even an extremely small amount of a bio material such as beta-amyloid protein or the like as a primary causal material of Alzheimer's disease, thereby being utilized for an early diagnosis of various diseases including the Alzheimer's disease.

The present invention may quickly and easily perform an early diagnosis for various diseases by using a relatively simple light transmission and photoelectric conversion scheme, instead of a gene analysis in a prior art.

In addition, the present invention is applicable to efficacy experiments for various drugs for understanding, monitoring and curing various types of diseases such as Alzheimer's disease.

While the invention has been shown and described with respect to the particular embodiments, it will be understood by those skilled in the art that various changes and modification may be made without departing from the scope of the invention as defined in the following claims.

What is claimed is:

1. An apparatus for detecting a bio material, the apparatus comprising:
a conjugate of a bio material and a fluorescent material which is excited and emits light of a lower energy than an energy of incident light by virtue of the fluorescent material when the light is incident;
an optical filter for allowing the excitation-emitted light from the conjugate, among the incident light, to be transmitted therethrough; and
a photoelectric conversion device for converting the light transmitted through the optical filter into an electric signal.

2. The apparatus of claim 1, further comprising:
a quantification processor for measuring the electric signal converted by the photoelectric conversion device to measure an amount of the bio material.

3. The apparatus of claim 1, wherein the optical filter is integrally formed on the photoelectric conversion device to reflect ultraviolet rays and transmit visible rays.

4. The apparatus of claim 1, wherein the optical filter uses, as an optical material, arsenic trisulfide (As₂S₃) or a compound obtained by doping a semiconductor material on the arsenic trisulfide.

5. The apparatus of claim 2, wherein the optical filter uses, as an optical material, arsenic trisulfide (As₂S₃) or a compound obtained by doping a semiconductor material on the arsenic trisulfide.

6. The apparatus of claim 3, wherein the optical filter uses, as an optical material, arsenic trisulfide (As₂S₃) or a compound obtained by doping a semiconductor material on the arsenic trisulfide.

7. The apparatus of claim 1, further comprising:
a microfluidic channel formed on the optical filter for guiding the conjugate to be located over a channel region of the photoelectric conversion device.

8. The apparatus of claim 1, wherein the optical filter is surface-processed by an extracellular matrix.

9. The apparatus of claim 7, wherein the optical filter is surface-processed by an extracellular matrix.

10. The apparatus of claim 1, wherein the bio material is beta-amyloid protein.

11. A method for detecting a bio material by a bio material detection apparatus, the method comprising:
exciting and emitting light of a lower energy than an energy of incident light by virtue of a fluorescent material when the light is incident into a conjugate of the bio material and the fluorescent material;
allowing the excitation-emitted light from the conjugate to be transmitted through an optical filter; and
converting the light transmitted through the optical filter into an electric signal.

12. The method of claim 11, further comprising:
measuring the converted electric signal to measure an amount of the bio material.

13. The method of claim 11, wherein the bio material is beta-amyloid protein.

14. A method for fabricating a photoelectric conversion device for converting excitation-emitted light from a conjugate of a bio material and a fluorescent material into an electric signal, the method comprising:
forming a photo transistor; and
forming an optical filter for allowing the excitation-emitted light from the conjugate, among incident light, to be transmitted therethrough, on the photo transistor.

15. The method of claim 14, wherein said forming an optical filter includes depositing an optical material, which reflects ultraviolet rays and transmits visible rays, on the photo transistor.

16. The method of claim 15, wherein said forming an optical filter includes using arsenic trisulfide (As₂S₃) as the optical material.

17. The method of claim 16, wherein said forming an optical filter includes doping a semiconductor material on the arsenic trisulfide.

18. The method of claim 14, wherein the bio material is beta-amyloid protein.
